(19) United States
(12) Patent Application Publication
(10) Pub. No.: US 2009/0140352 A1
(43) Pub. Date: Jun. 4, 2009

(54) METHOD OF FORMING INTERLAYER DIELECTRIC FOR SEMICONDUCTOR DEVICE

(76) Inventor: Jin-Kyu Lee, Gangnam (KR)

Correspondence Address: SHERR & VAUGHN, PLLC, 620 HERNDON PARKWAY, SUITE 200, HERNDON, VA, 20170, US

(21) Appl. No.: 12/325,170

(22) Filed: Nov. 29, 2008

(30) Foreign Application Priority Data
Dec. 3, 2007 (KR) 10-2007-0124436

(51) Int. Cl. H01L 21/768; H01L 29/78

(52) U.S. Cl. 257/408; 438/653; 257/E21.584; 257/E29.266

(57) ABSTRACT

A method of forming an interlayer dielectric for a semiconductor device minimizing voids. During a process for forming a PMD oxide film being used as an interlayer dielectric, since TEOS impurities are added under a low-pressure controlled atmosphere, and gap filling characteristics are improved. Therefore, voids are minimized in the PMD oxide film. As a result, contact holes are prevented from shorting with each other through a void, and thus current leakage is suppressed. Further, it is not necessary to perform a rapid thermal anneal to improve the density of the PMD oxide film, nor to deposit a second PMD oxide film after planarization. As a result, the manufacturing process can be simplified.

The present application claims priority under 35 U.S.C. 119 to Korean Patent Application No. 10-2007-0124436 (filed on Dec. 3, 2007), which is hereby incorporated by reference in its entirety.

### BACKGROUND

With higher density integration of semiconductor devices, design rules require device patterns to be further miniaturized. It has become more difficult to deposit an insulator in gaps etched between devices to provide electrical insulation. Therefore, a chemical vapor deposition (CVD) process having good gap filling characteristics may be used.

FIGS. 1A to 1F illustrate a manufacturing process for a semiconductor device, and in particular, a method of forming an interlayer dielectric, according to the related art. Referring to FIG. 1A, a gate oxide film 12 and a gate poly layer 13 may be formed on and/or over a semiconductor substrate 11. Then, the gate poly layer 13 may be selectively removed using a photoresist pattern by way of exposure and etching, thereby forming a gate electrode. A process for low-concentration ion implantation may be performed to form LDD (Low Doped Drain) regions 14 on the left and right sides of the gate poly layer 13. A nitride film 15 may be formed on and/or over the entire structure in which the gate electrode is formed. The nitride film 15 may be over-etched to form sidewall spacers on and/or over the left and right side surfaces of the gate poly layer 13. The nitride film 15 on and/or over the gate poly layer 13 may be removed by way of over-etching due to a low step. High-concentration impurity ions may be implanted into the LDD regions 14 on the left and right sides of the gate poly layer 13, thereby forming a source and drain region 16. The sidewall spacers formed from the nitride film 15 block implantation of the impurity ions, and define the source and drain region 16.

Referring to FIG. 1B, a thin silicon nitride film to be used as an etch stop film 17 may be formed on and/or over the entire surface of the substrate over which the gate electrode is formed. A first PMD (Poly Metal Dielectric layer) oxide film 18a being used as an interlayer dielectric may be made from BPSG (BoroPhospho Silicate Glass) or PSG (Phospho Silicate Glass), which may be deposited or annealed over the entire upper surface of the etch stop film 17. The first PMD oxide film 18a may be formed by first thinly depositing BPSG or PSG in the form of a liner, then depositing to have a desired thickness by way of atmospheric pressure CVD (APCVD) or sub-atmospheric CVD (SACVD). A process for RTA (Rapid Thermal Annealing) may be performed to improve the density of the first PMD oxide film 18a.

Referring to FIG. 1C, the first PMD oxide film 18a may be planarized by a chemical mechanical polishing (CMP) process. Next, TEOS may be evenly deposited on and/or over the first PMD oxide film 18a by way of APCVD or SACVD, thereby forming a second PMD oxide film 18b. A mask pattern for defining a contact hole region may be formed on and/or over the second PMD oxide film 18a. Using this mask pattern, the second PMD oxide film 18b and the first PMD oxide film 18a may be dry etched. The underlying etch stop film 17 may also be dry etched. Next, the mask pattern may be removed. A contact hole 19 through which the source and drain region 16 is exposed may be formed to pass through the second PMD oxide film 18b, the first PMD oxide film 18a, and the etch stop film 17.

Referring to FIG. 1D, a reactive metal layer 20, for example, a Ti metal layer, may be formed on and/or over the second PMD oxide film 18b, in which the contact hole 19 is formed, by plasma enhanced CVD (PECVD), CVD, or physical vapor deposition (PVD). Next, a barrier metal layer 21, for example TiN, may be deposited on and/or over the reactive metal layer 20 by way of LPCVD.

Referring to FIG. 1E, tungsten (W) 22, a conductive material, may be deposited by CVD to fill the contact hole 19 in which the barrier metal layer 21 is formed. Referring to FIG. 1F, a CMP process may be performed until the surface of the second PMD oxide film 18b is exposed. Then, tungsten 22, the barrier metal layer 21, and the reactive metal layer 20 may be polished to form a contact plug. With higher density integration of semiconductor devices, the device size and the line width are inevitably decreased. In particular, as a gap between gate electrodes becomes narrower, the gap filling property of the interlayer dielectric becomes an important factor for implementing a fine line width.

In the related manufacturing process for a semiconductor device described above, to form the interlayer dielectric, impurities such as BPSG or PSG are added under an atmosphere. This manufacturing process is effective for improving the device characteristics, but the gap between the gate electrodes may be narrow. For this reason, as shown in FIG. 1B, a void 18c may be formed in the first PMD oxide film 18a or the second PMD oxide film 18b. Then, during the metal deposition and filling process shown in FIGS. 1D and 1E, metal components enter the void 18c. As a result, as shown in FIG. 1F, when the contact plug is formed, adjacent contact holes may be connected to each other. This may lead to current leakage and adversely affect the reliability of the semiconductor device.

### SUMMARY

Embodiments relate to a method of forming an interlayer dielectric for a semiconductor device. In particular, embodiments relate to a method of forming an interlayer dielectric for a semiconductor device which forms a PMD (Poly Metal Dielectric) film serving as an interlayer dielectric using a TEOS (tetraethyl orthosilicate) film by way of low pressure chemical vapor deposition (LPCVD), thereby improving gap filling properties.

In embodiments, gap filling characteristics may be maximized by forming a PMD film serving as an interlayer dielectric using a TEOS film by way of LPCVD. Embodiments thereby minimize contact holes from being connected to each other through a void, and to thereby suppress occurrence of current leakage.

According to embodiments, a method of forming an interlayer dielectric for a semiconductor device includes: providing a semiconductor substrate having at least one active region, forming an etch stop film over the entire surface of the substrate to serve as an etch stop point, forming an oxide film as an interlayer dielectric over the entire surface of the etch stop using a tetraethyl orthosilicate film by low pressure chemical vapor deposition, and forming a contact hole for forming a connection with at least one of an active region of a semiconductor substrate and a metal wiring line.

According to embodiments, during a process for forming a PMD oxide film being used as an interlayer dielectric, since TEOS impurities are added under a low-pressure controlled atmosphere, and gap filling characteristics are improved. Therefore, voids are minimized in the PMD oxide film. As a result, contact holes are prevented from shorting with each other through a void, and thus current leakage is suppressed. Further, it is not necessary to perform a rapid thermal anneal to improve the density of the PMD oxide film, nor to deposit a second PMD oxide film after planarization. As a result, the manufacturing process can be simplified.

### DRAWINGS

FIGS. 1A to 1F illustrate a manufacturing process for a semiconductor device using a method of forming an interlayer dielectric.

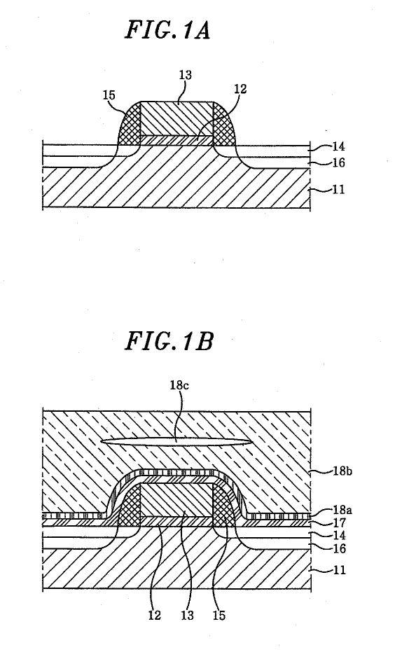

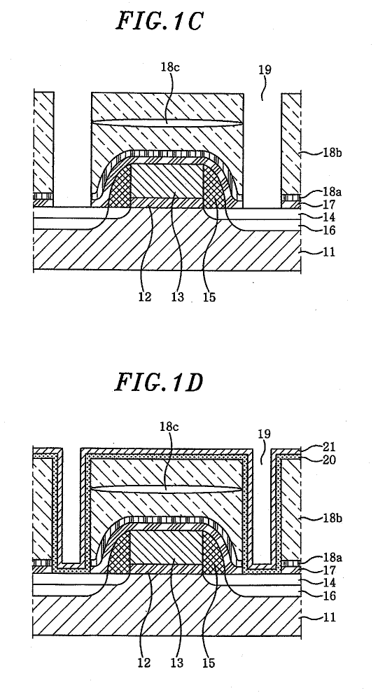

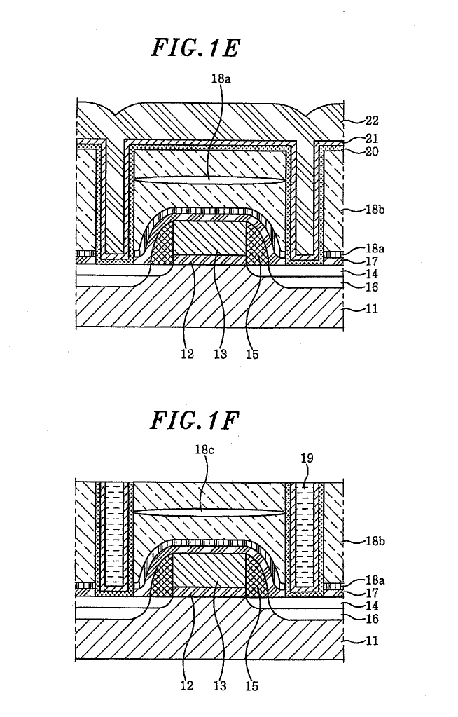

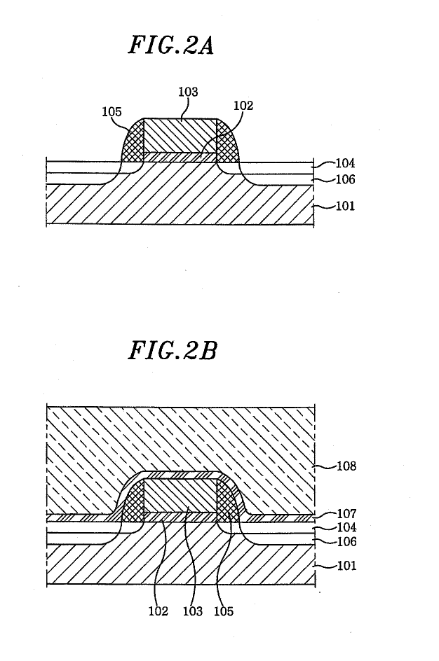

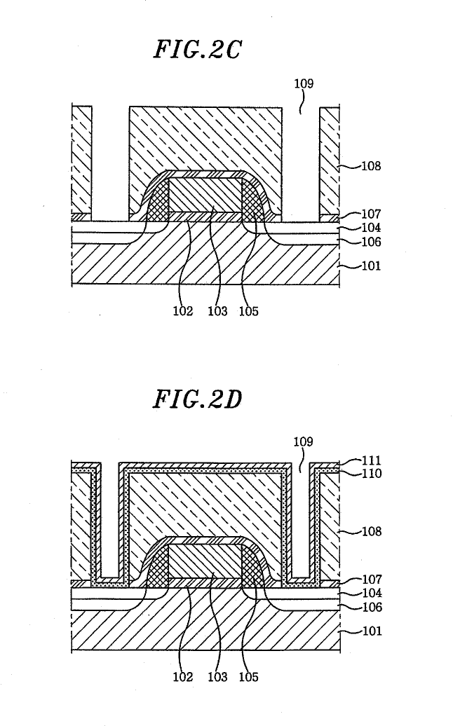

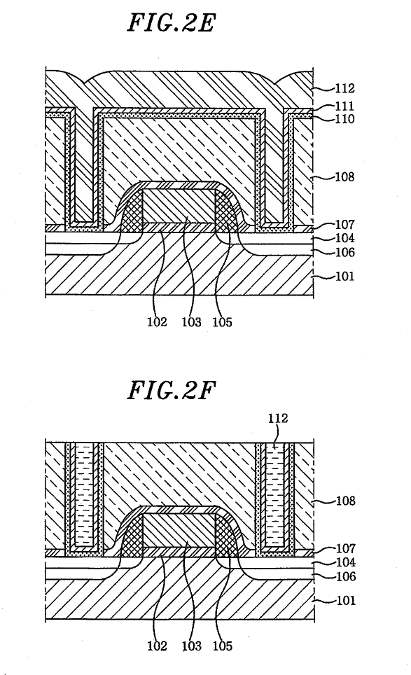

Example FIGS. 2A to 2F illustrate a manufacturing process for a semiconductor device using a method of forming an interlayer dielectric according to embodiments.

### DESCRIPTION

Example FIGS. 2A to 2F illustrate a manufacturing process for a semiconductor device using a method of forming an interlayer dielectric according to embodiments. Referring to FIG. 2A, a gate oxide film 102 and a gate poly layer 103 may be formed on and/or over a semiconductor substrate 101. Next, the gate poly layer 103 may be selectively removed using a photoresist pattern with an exposure and etching process, thereby forming a gate electrode.

A low-concentration ion implantation process may be used to form LDD regions 104 on and/or over the left and right sides of the gate poly layer 103. Next, a nitride film 105 may be formed on and/or over the entire structure in which the gate electrode is formed. The nitride film 105 may be over-etched so that the nitride film 105 on and/or over the left and right side surfaces of the gate poly layer 103 remains as sidewall spacers. The nitride film 105 on and/or over the gate poly layer 103 may be removed by way of over-etching due to a low step. High-concentration impurity ions may be implanted into the LDD regions 104 on the left and right sides of the gate poly layer 103, thereby forming a source and drain region 106. The sidewall spacers made from the nitride film 105 block implantation of the impurity ions, and define the source and drain region 106. Silicide may be deposited and annealed on and/or over the entire surface to form a silicide film on and/or over the surfaces of the gate poly layer 103 and the source and drain region 106. Electrical resistance can be reduced by using the silicide film.

Referring to example FIG. 2B, a thin silicon nitride film or silicon oxide film (for example, SiO₂, Si₃N₄, or SiON) may be formed on and/or over the entire surface of the substrate, including the gate electrode, to serve as an etch stop film 107. A PMD oxide film 108 used as an interlayer dielectric may be formed on and/or over the entire upper surface of the etch stop film 107. The PMD oxide film 108 may be formed by first depositing a thin TEOS liner and then depositing TEOS by LPCVD to a desired thickness. For example, in the case of a LDI (LCD drive IC) device of 0.13 to 0.65 μm, the temperature of the process chamber may be maintained at approximately 649 to 651° C. The PMD oxide film 108 may be first deposited in the form of liner with a thickness ranging from 750 Å to 800 Å, and then deposited to a desired thickness ranging from 1,200 Å to 9,000 Å. Alternatively, the PMD oxide film 108 may be first deposited in the form of liner with a thickness ranging from 750 Å to 850 Å and then deposited to a desired thickness ranging from 7,800 to 10,200 Å.

Referring to example FIG. 2C, the PMD oxide film 108 is planarized by a CMP process. Compared to the related art, the process for forming the PMD oxide film 108 according to embodiments, adds TEOS impurities under a low-pressure controlled atmosphere. Gap filling characteristics are improved, and no void is formed in the PMD oxide film 108. It is not necessary to perform an RTA process or deposit a second PMD oxide film after planarization. Therefore, the manufacturing process can be simplified. Thereafter, a mask pattern for defining a contact hole region may be formed on and/or over the PMD oxide film 108. Using this mask pattern, the PMD oxide film 108 may be dry etched, and the underlying etch stop film 107 may also be etched by dry etching. Then, a contact hole 109 through which the source and drain region 106 is exposed may be formed through the PMD oxide film 108 and the etch stop film 107.

Referring to example FIG. 2D, a reactive metal layer 110, for example, a Ti metal layer, may be deposited by PECVD, CVD, or PVD on and/or over the PMD oxide film 108 in which the contact hole 109 is formed. Next, a barrier metal layer 111, for example, TiN may be deposited on and/or over the reactive metal layer 110 by LPCVD. Before the barrier metal layer 111 is deposited, the reactive metal layer 110 may be subject to heat treatment at approximately 550° C. to 800° C. under vacuum conditions or a nitrogen atmosphere, to form an ohmic layer made of a silicide compound. The barrier metal layer 111 may be formed on and/or over the ohmic layer.

Referring to example FIG. 2E, the conductive material tungsten (W) 112 may be deposited, for example by CVD, 109 on and/or over the barrier metal layer 111 to fill the contact hole 109. Referring to example FIG. 2F, a CMP process may be performed until the surface of the PMD oxide film 108 is exposed. Then, the tungsten 112, the barrier metal layer 111, and the reactive metal layer 110 may be polished to form a contact plug. For example, in embodiments, a semiconductor device, such as a transistor (reference number 103 corresponds to a gate electrode of a transistor), may be embedded between the PMD oxide film 108 and the semiconductor substrate 101. This means that the interlayer dielectric is formed after a manufacturing process for a semiconductor device is performed, rather than being formed directly on the semiconductor substrate. Of course, embodiments can be applied to a contact for connecting a metal wiring line and an active region of a semiconductor substrate, and connecting a metal wiring line and a metal wiring line. Therefore, there may be no additional semiconductor device between the interlayer dielectric and the active region.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
providing a semiconductor substrate having at least one active region; and then
forming an etch stop film over the entire surface of the semiconductor substrate; and then
forming an oxide film as an interlayer dielectric over the entire surface of the etch stop film using a tetraethyl orthosilicate film by low pressure chemical vapor deposition; and then
forming a contact hole for forming a connection with at least one of the active region and a metal wiring line.

2. The method of claim 1, wherein forming an etch stop film includes forming a silicon nitride film as the etch stop film.

3. The method of claim 1, wherein forming an etch stop film includes forming a silicon oxide film as the etch stop film.

4. The method of claim 1, wherein forming an etch stop film includes forming a SiON film as the etch stop film.

5. The method of claim 1, wherein the oxide film is first deposited as a thin liner, and then deposited to a desired thickness.

6. The method of claim 5, wherein, in providing a semiconductor substrate having at least one active region, the semiconductor and active region are suitable for forming a liquid crystal display drive integrated circuit device of 0.13 to 0.65 μm.

7. The method of claim 6, further comprising depositing the thin liner with a thickness in a range between approximately 750 Å to 850 Å.

8. The method of claim 7, further comprising depositing the oxide with a desired thickness in a range between approximately 7,800 to 10,200 Å.

9. The method of claim 5, including depositing a reactive metal layer in the contact hole.

10. The method of claim 9, including subjecting the reactive metal layer to a heat treatment to form a silicide.

11. The method of claim 10, including performing the heat treatment under conditions of vacuum.

12. The method of claim 9, including depositing a barrier metal layer over the reactive metal layer in the contact hole.

13. The method of claim 12, including filling the contact hole with tungsten deposited over the barrier metal layer.

14. The method of claim 12, including performing polishing process over the tungsten layer, the barrier metal layer, and the reactive metal layer to form a contact plug.

15. The method of claim 1, wherein a temperature of a process chamber used in performing the low pressure chemical vapor deposition is maintained at approximately 649 to 651° C.

16. An apparatus comprising:
a semiconductor substrate;
a gate oxide film formed over the semiconductor substrate;
a gate poly layer formed over the gate oxide film, the gate oxide film and gate poly layer together forming a gate electrode;
a nitride film formed over the semiconductor substrate including the gate electrode;
lightly doped drain regions with low-concentration impurity ions formed on left and right sides of the gate poly layer;
a source region and drain region with high-concentration impurity ions implanted into the lightly doped drain regions on left and right sides of a gate poly layer;
an etch stop film formed over the semiconductor substrate including the gate electrode;
a poly metal dielectric oxide film serving as an interlayer dielectric formed over the etch stop film; and
a first tungsten plug formed over the source region and a second tungsten plug formed over the drain region.

17. The apparatus of claim 16, wherein the etch stop film is a silicon nitride film.

18. The apparatus of claim 16, wherein the etch stop film is a silicon oxide film.

19. The apparatus of claim 16, wherein the oxide film has a thickness in a range between approximately 7,800 to 10,200 Å.

20. The apparatus of claim 19, wherein the apparatus is suitable for forming a liquid crystal display drive integrated circuit device of 0.13 to 0.65 μm.
